(19) United States
(12) Patent Application Publication
(10) Pub. No.: US 2011/0133793 A1
(43) Pub. Date: Jun. 9, 2011

(54) CLOCK DIVIDER WITH SEAMLESS CLOCK FREQUENCY CHANGE

(75) Inventors: David W. Wheelock, Longmont, CO (US); Daniel C. Graham, Longmont, CO (US)

(73) Assignee: SEAGATE TECHNOLOGY LLC, Scotts Valley, CA (US)

(21) Appl. No.: 12/630,610

(22) Filed: Dec. 3, 2009

(51) Int. Cl. H03K 23/00

(52) U.S. Cl. 327/115

(57) ABSTRACT

A clock divider circuit including a clock input, a clock selection input, a divider stage and a toggle stage is provided. The clock divider circuit provides an output clock based on a clock input received at the clock input. The clock selection input is coupled to the divider stage, and the divider stage is coupled to the toggle stage. A clock divide setting is updated at the clock selection input synchronously to an operation of the divider stage. In one implementation, for example, the clock divider setting is updated seamlessly. A method of transitioning an output clock signal is also provided. The method includes receiving an input clock signal and a first clock divide setting; providing an output clock signal having a first output clock frequency by dividing the input clock signal based upon the first clock divide setting utilizing a divider stage of a clock divider circuit; providing an updated second clock divide setting synchronously to an operation of the divider stage; and transitioning the output clock signal to a second output clock frequency based upon the updated second clock divide setting. A power management system is also provided.

### SUMMARY

Implementations described and claimed herein provide a clock divider circuit that provides real-time clock frequency changes.

In one implementation, a clock divider circuit includes a clock input, a clock selection input, a divider stage and a toggle stage. The clock divider circuit provides an output clock based on a clock input received at the clock input. The clock selection input is coupled to the divider stage, and the divider stage is coupled to the toggle stage. A clock divide setting is updated at the clock selection input synchronously to the operation of the divider stage. In one implementation, for example, the clock divider setting is updated seamlessly.

In another implementation, a method of transitioning an output clock signal is provided. The method includes receiving an input clock signal and a first clock divide setting; providing an output clock signal having a first output clock frequency by dividing the input clock signal based upon the first clock divide setting utilizing a divider stage of a clock divider circuit, the divider stage comprising a counter period; providing an updated second clock divide setting synchronously to the operation of the divider stage; and transitioning the output clock signal to a second output clock frequency based upon the updated second clock divide setting.

In yet another implementation, a power management system is also provided.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTIONS OF THE DRAWINGS

FIG. 1 illustrates an example of an output divided clock signal showing a pause between transitions in the output clock frequency.

FIG. 2 illustrates an example representation of a clock divider circuit that provides seamless real-time clock frequency transitions.

FIG. 3 illustrates an example of an output divided clock signal showing a seamless real-time transition in the output clock frequency without a pause or glitch in the output divided clock signal.

FIG. 4 illustrates another example representation of a clock circuit that provides seamless real-time clock frequency transitions.

FIG. 5 illustrates an example linear feedback shift register (LFSR) clock divider circuit that may be used as a clock divider circuit in the implementations of FIG. 2 or 4.

FIG. 6 illustrates an example synchronization circuit that may be used in conjunction with the example clock divider circuit of FIG. 5.

FIG. 7 illustrates an example divider selection circuit that may be used in conjunction with FIGS. 5 and 6.

FIG. 8 illustrates example operations for seamlessly changing a clock divider output frequency in real-time.

FIG. 9 illustrates an example of a timing diagram depicting demand and clock frequency adjustments of an example electronic system.

### DETAILED DESCRIPTIONS

An integrated circuit may use a clock divider circuit to provide varying clock settings. In one particular implementation, different operational modes of an electronic device may utilize different clock frequencies. For example, a relatively high clock frequency may be provided to a circuit (e.g., a processor) in a high performance operational mode, while a relatively lower clock frequency may be provided to that same circuit in a low power operational mode. Switching the clock frequency from one frequency to another, however, may negatively impact the operation of the circuit. A glitch or pause in the clock signal may, for example, cause system instability, negatively impact performance, or even cause a system reset. A pause in the clock signal may temporarily stop the operation of the circuit. Where the circuit is switching from a low power setting to a high performance setting, for example, the pause may delay operation of the circuit when it should be operating in a high performance operational mode.

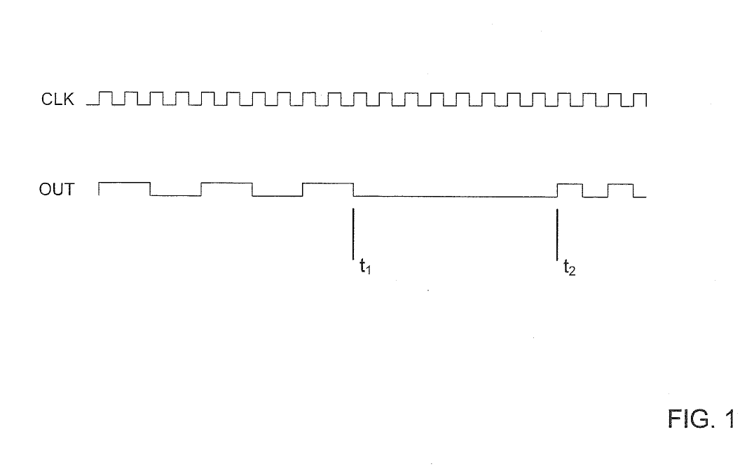

FIG. 1 shows an example of a pause in a clock signal generated in a switch from a Divide-by-Four clock setting to a Divide-by-Two clock setting. A top waveform shown in FIG. 1 shows an input clock signal CLK that is provided to a clock divider circuit that provides an output clock signal OUT. The output clock signal OUT is shown directly below the input clock signal CLK in FIG. 1. The initial frequency of the output clock signal OUT corresponds to the input clock signal divided by four before time t1. After time t2, however, the clock divider has changed the output clock signal from the Divide-by-Four setting to a Divide-by-Two setting that corresponds to one-half of the input clock signal CLK. A pause, denoted by the time period between time t1 and time t2, provides a gap between the first output frequency and the second output frequency. During this time period, the output clock signal OUT is inactive and is not driving the operation of the circuit. Where, as in this example, the output clock signal frequency is being increased (e.g., to increase performance of an electronic circuit), such a pause may slow the operation of the electronic circuit at a time when higher performance levels are desired.

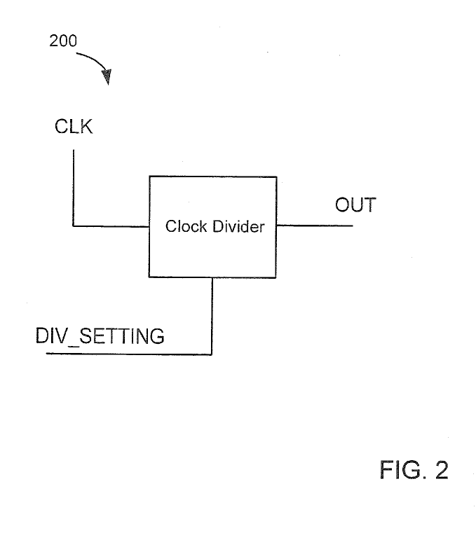

FIG. 2 shows an example of a clock divider circuit 200. The clock divider circuit 200 may comprise any clock divider circuit, such as a programmable clock divider, a non-programmable clock divider, a simple divider (e.g., a counter-based clock divider circuit), a divider end-count indication divider circuit, a feedback-based clock divider (e.g., a linear feedback shift register (LFSR) clock divider circuit), a state machine-based divider, or the like. The clock divider circuit 200 comprises state knowledge (on its own or provided for it) that can be used to determine when to reload its divide setting that determines its operation.

The clock divider circuit 200 receives an input clock signal CLK and converts that input clock signal CLK to an output clock signal OUT by dividing the input clock signal CLK based upon a divide setting control input DIV_SETTING. The divide setting represents an integer divisor (e.g., 1, 2, 3, . . . , N) that may be used by the clock divider circuit 200 to divide the input clock signal CLK to obtain the output clock signal OUT. The divide setting control input DIV_SETTING may be determined in any number of ways. The input DIV_SETTING, for example, may be generated by another circuit and provided to the clock divider circuit 200. In another implementation, for example, the input DIV_SETTING may be retrieved from a data storage location (e.g., a register) and provided to the clock divider circuit 200.

In a counter-based implementation, for example, the clock divider circuit 200 operates by loading the divide setting control signal DIV_SETTING and initiating a counter operation of the clock divider circuit 200 using that divide setting control input DIV_SETTING. After the counting operation is complete, the clock divider circuit 200 reloads the divide setting control input DIV_SETTING and restarts the counter operation, again using the divide setting control input.

In the clock divider circuit 200, the divide setting control input DIV-SETTING is synchronized with an end-count indication of the clock divider circuit 200. By synchronizing the divide setting control input and the end-count indication, the clock divider circuit 200 can seamlessly switch from one output clock frequency to another output clock frequency. As used herein, a “seamless” switch or transition refers to a glitch-less and pause-free transition in the output clock signal OUT from a first frequency to a second frequency different from the first frequency.

The seamless transition from one clock frequency to another clock frequency by the clock divider circuit 200 is accomplished by dynamically updating a clock divider setting of the clock divider circuit 200 synchronously to the operation of the clock divider circuit 200 (e.g., at the end of a clock divider count period). Since the clock divider circuit 200 loads the divide setting control input DIV_SETTING at the beginning of a clock divider count period in a counter-based implementation, the divide setting control input DIV_SETTING can be updated during the clock divider count period without affecting the ongoing operation of the clock divider circuit 200. If the divide setting control input DIV_SETTING is updated during this period, the clock divider circuit 200 can load the new input prior to starting a new clock divider count period. This allows the clock divider circuit 200 to switch between output clock frequencies without any pauses or glitches in the output clock signal OUT.

In one particular implementation, this enables the use of power saving hardware to operate autonomously from system firmware without requiring downstream hardware to be tolerant of pauses in the clock stream or requiring that firmware be cognizant of the clock configuration. A clock divider running at 1000 MHz may, for example, have eight pre-programmed divider selections implemented to dynamically select between Divide-by-Three through Divide-by-Ten options. The resulting clock divider in this example can seamlessly switch between the following clock options: 333 MHz, 250 MHz, 200 MHz, 166 MHz, 142 MHz, 125 MHz, 111 MHz, and 100 MHz.

The divider settings can be pre-programmed or dynamically generated. In one particular implementation, for example, pre-programmed settings may be used for various power levels (e.g., 100% for full performance, 75%, 50%, 33%, 25%, and 1% for a sleep application). These pre-programmed settings can result in a wide range of clock speed settings based on a particular input PLL frequency and available integer divider values in the clock generation circuit. In another implementation, however, the divider setting can be dynamically generated based on resource needs within an electronic device.

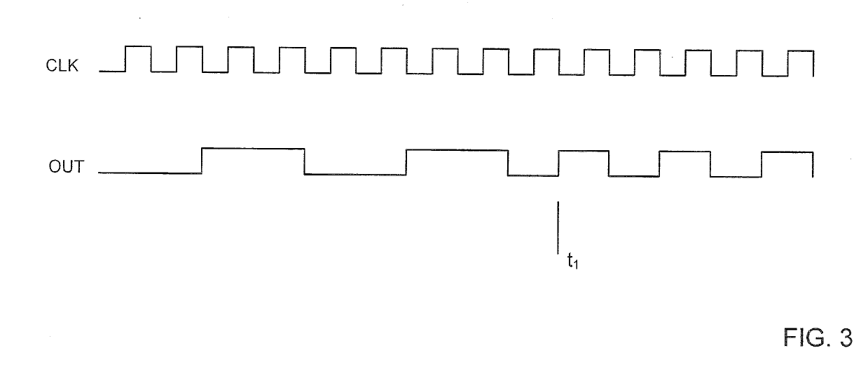

FIG. 3 shows an example of a seamless transition in an output clock signal OUT generated from an input clock signal CLK. In FIG. 3, for example, the output clock signal OUT transitions from a Divide-by-Four clock signal generated from the input clock signal CLK to a Divide-by-Two clock signal at time t₁ without a pause or glitch in the output clock signal OUT.

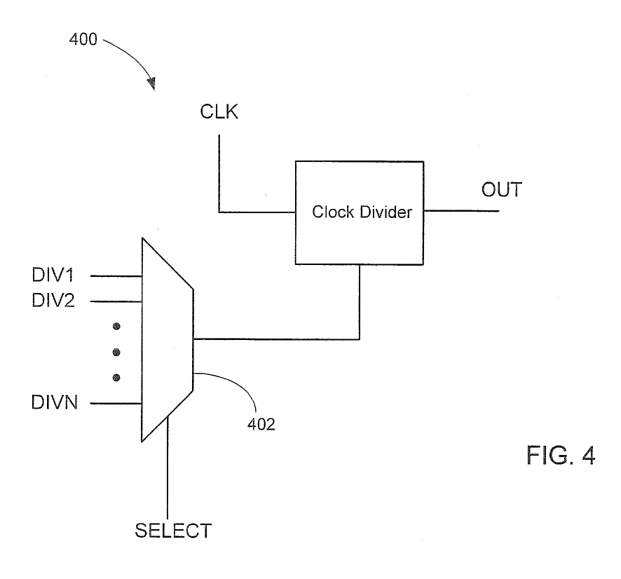

FIG. 4 shows another implementation of a clock divider circuit 400. In the particular implementation of FIG. 4, for example, a multiplexer 402 selects from a plurality of divide setting control values DIV1, DIV2, . . . , DIVN, although any number of divide setting control values. The individual control values DIV1 through DIVN may be pre-programmed (e.g., in a register, cache, or other data storage device) or may be generated dynamically (e.g., based on operational conditions of the electronic device).

An input SELECT to the multiplexer 402 is used to select one of the input divide setting control values to be provided to the clock divider circuit 400. The input SELECT, for example, may be provided by a different circuit that operates independently of the output clock signal OUT of the clock divider circuit 400. A low power circuit that provides the SELECT signal to the multiplexer 402, for example, may operate on the input clock signal CLK (or another clock value). In this implementation, even if the clock divider circuit is providing a very low frequency clock signal OUT to the majority of an electronic device in order to conserve power, a quickly responding circuit may be used to detect a demand for a higher clock value and provide the input SELECT to the multiplexer to provide a different divide setting control value to the clock divider circuit 400. As discussed above with respect to FIG. 2, the new divide setting control value is provided to (e.g., written to) the clock divider circuit 400 synchronously to the operation of the clock divider circuit 400 (e.g., during a clock divider count period). In this manner, the new divide setting control value will be synchronously available to the clock divider circuit 400 (e.g., when the current clock divider count period is complete), and the clock divider circuit 400 can seamlessly transition the output clock signal OUT to a new output clock frequency.

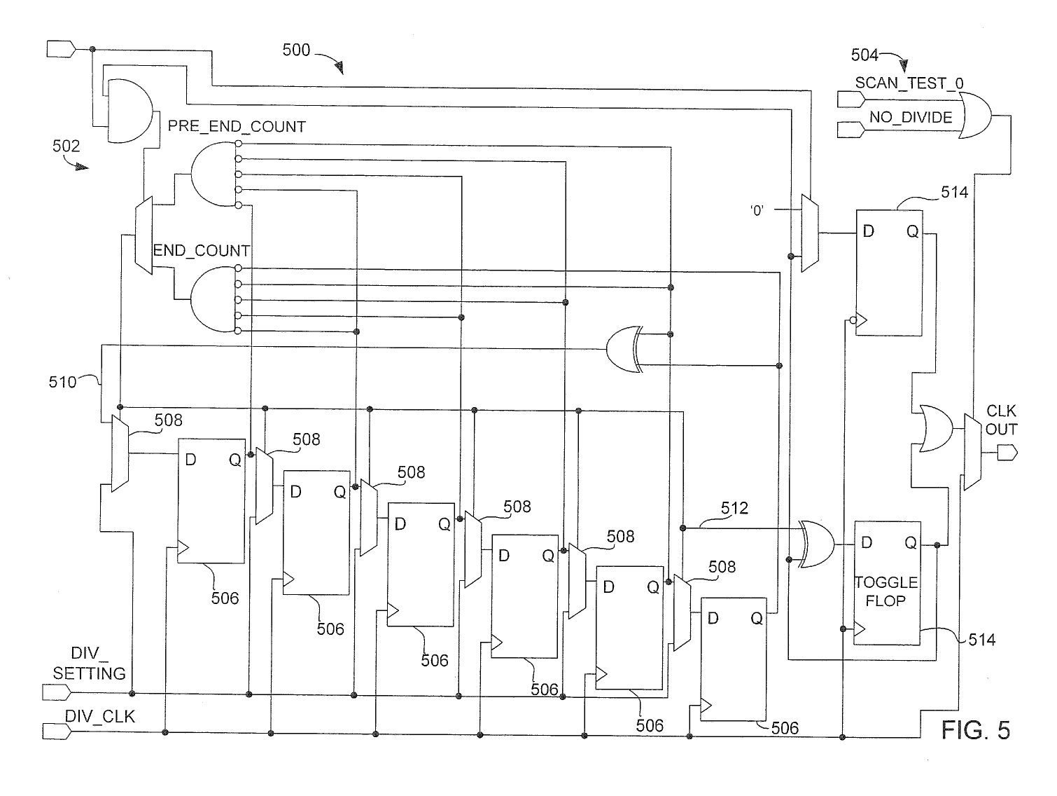

FIG. 5 shows an example linear feedback shift register (LFSR) programmable clock divider circuit 500. The programmable clock divider circuit 500 comprises a divider stage 502 and a toggle stage 504. The divider stage 502 of the programmable clock divider circuit 500 receives an input clock signal DIV_CLK and a divide setting control signal DIV_SETTING. The divide setting control signal DIV_SETTING can be implemented in many different ways, for example, a control signal, a register value, a voltage with an analog-to-digital (A/D) conversion added to the circuitry, or the like. In this particular implementation of a LFSR programmable clock divider circuit 500, the input clock signal DIV_CLK drives a plurality of D flip-flops 506 of the divider stage 502. The divide setting control signal DIV_SETTING is initially applied to the flip-flops 506 via a corresponding plurality of multiplexers 508. The multiplexers 508 select the DIV_SETTING value synchronously to the operation of the divider stage 502 (e.g., at the beginning of a count period of the LFSR programmable counter-based clock divider circuit 500). The divider stage 502 of the LFSR programmable clock divider circuit 500 implements a polynomial-based counter that increments for a period of time based upon a value of the divide setting control signal DIV_SETTING. Although a counter-based clock divider circuit is shown in FIG. 5, other types of clock divider circuits, such as those described above, could be used.

During the count period, the multiplexers select a feedback signal 510 that is generated from output signals of the final two flip-flops of the plurality of flip-flops 502. A signal generated by a PRE_END_COUNT circuit and an END_COUNT circuit is used to select either the divide setting control signal DIV_SETTING or the feedback signal 510 to provide to the plurality of flip-flops 506 of the divider stage 502. The PRE_END_COUNT and END_COUNT circuits provide signals that are used to enable the selection of the next divide setting control signal DIV_SETTING after the completion of one counter period of the divider stage 502 and prior to the beginning of the next counter period. Since the divide setting control signal DIV_SETTING is used only at the beginning of a counter period of the divider stage 502, the divide setting control signal DIV_SETTING may be updated during a counter period of the divider stage 502 of the programmable clock divider circuit 500. As long as the divide setting control signal is updated before it is accessed at the beginning of a new counter period, the programmable clock divider circuit 500 can seamlessly transition from one output clock frequency to another output clock frequency without a pause or glitch in the output clock signal CLKOUT.

An output 512 of the divider stage 502 is provided to the toggle stage 504 to generate an output clock CLKOUT of the programmable clock divider circuit 500. The toggle stage 504 comprises a pair of flip-flops 514 that are used to generate the output clock CLKOUT of the programmable clock divider circuit 500.

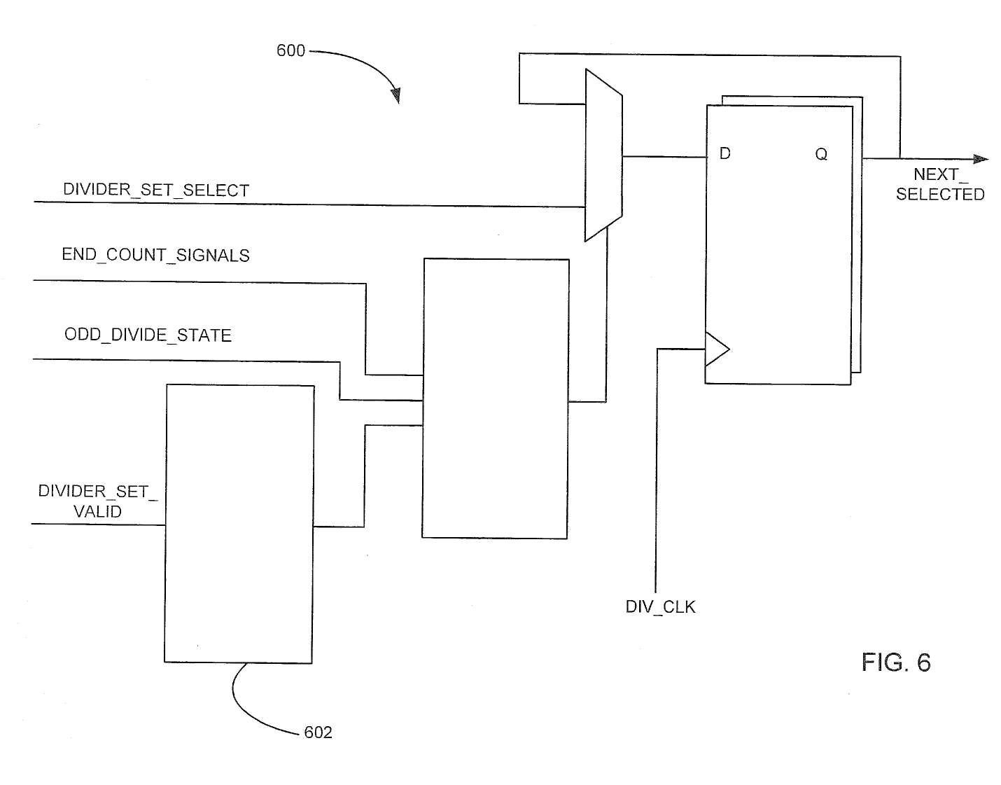

FIG. 6 shows an example of a synchronization circuit 600 that may be used to select the next divide setting selection. The synchronization circuit 600 includes a synchronizer 602 running on the input clock signal DIV_CLK that is also provided as the input clock signal to be divided in a clock divider circuit. Inputs DIVIDER_SET_SELECT and DIVIDER_SET_VALID are received from clock control circuitry running asynchronously to the input clock signal DIV_CLK. A new set selection is allowed to propagate only if the “valid” signal has been re-sampled in the DIV_CLK domain, and when the divider clock is not in the process of updating the divider settings (e.g., when the divider clock is one clock period from updating the divider settings). In the particular example shown in FIG. 5, for example, this is determined by the PRE_END_COUNT circuit and the END_COUNT circuit.

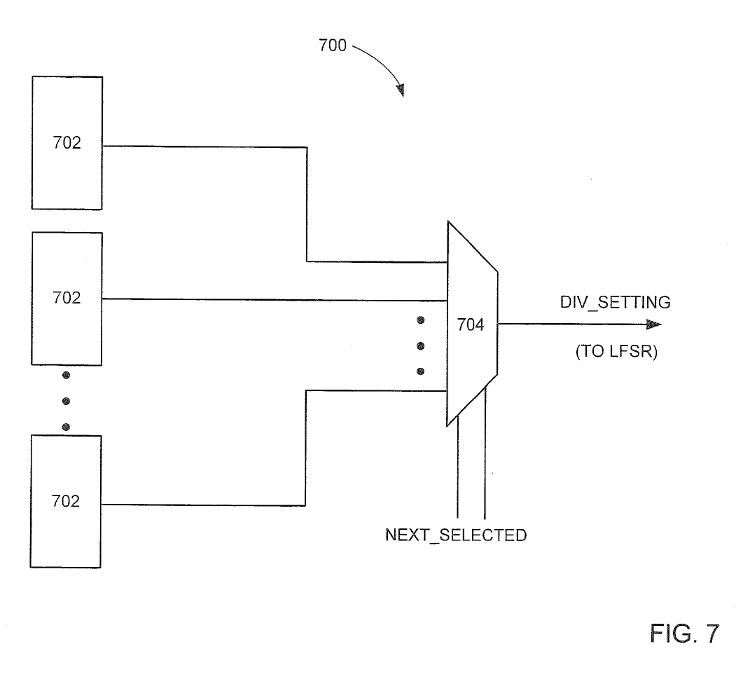

FIG. 7 shows an example of a divider selection circuit 700. In this particular implementation, the divider selection circuit 700 includes N banks 702 of preprogrammed (or automatically generated) divider selections that may be used to determine an output clock frequency for a clock divider circuit. The N banks 702 may comprise any type of data storage mechanism, such as registers, cache, memory, or the like. The N banks 702 are connected as inputs to a multiplexer 704 that is controlled by a selection signal, such as an output signal NEXT_SELECTION from the synchronization circuit 600 shown in FIG. 6. The divider selection circuit 700 may ran asynchronously to the input clock signal DIV_CLK provided to the clock divider circuit. In the particular implementation shown in FIG. 7, the output of the multiplexer 704 of the divider selection circuit 700 provides a divide control signal DIV_SETTING, such as the one provided as an input to the programmable counter-based clock divider circuit 500 shown in FIG. 5.

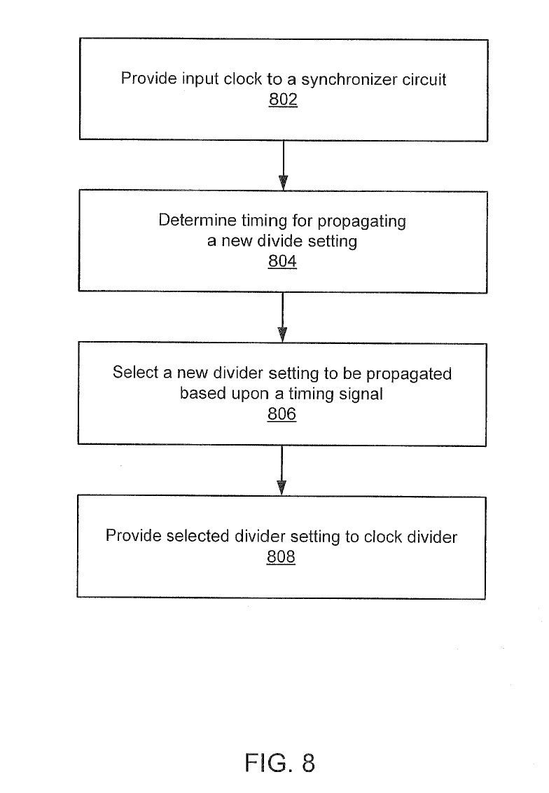

FIG. 8 shows example operations 800 for seamlessly changing a clock divider output frequency in real-time. An input clock to be divided is provided to a synchronizer circuit in operation 802. The synchronizer circuit uses the input clock to determine a timing for propagating a new divide setting selection to a divider circuit in operation 804. The synchronizer circuit, for example, may time the propagation of the new divide setting to occur synchronously to the operation of the divider circuit (e.g., during a counter period of a counter stage of the clock divider circuit). In one particular implementation, for example, the synchronizer circuit times the propagation of a new divide setting to a valid signal being re-sampled in the input clock domain and when a counter stage of the divider circuit is one clock from updating to begin a new counter period.

A divider setting selection circuit selects a new divider setting to be propagated based upon a timing signal provided by the synchronization circuit in operation 806. The divider setting may be selected from a preprogrammed or dynamically generated divider setting value. In one particular implementation, for example, preprogrammed divider settings may reside in one or more registers and may be selected based upon the timing signal provided by the synchronization circuit. The selected divider setting is provided as an input to the clock divider circuit in operation 808.

The divider setting input to the clock divider circuit may, for example, be synchronously provided to a stage (e.g., a counter stage) of the clock divider circuit to be used to select a divide ratio for the clock divider circuit. In an example counter-based implementation, for example, the counter stage of the clock divider circuit receives the divider setting input at the beginning of a counter period in which a feedback path is used during the remainder of the counter period. In this particular implementation, the divider setting input is not used by the counter stage of the clock divider circuit until the divider setting input is reloaded into the counter stage at the beginning of a subsequent counter period.

Since the divider setting input is not used during the counter period of the clock stage in this implementation, the divider setting input may be updated during the counter period without affecting the ongoing operation of the clock divider circuit. If the divider setting input is updated during a counter period of the clock divider circuit counter stage, however, the new divider setting input is loaded into the counter stage at the beginning of the next counter period of the clock divider circuit. This allows the clock divider circuit to seamlessly transition from one clock frequency to another clock frequency without creating any pauses or glitches in the output clock signal. Since the new divider setting is introduced at the beginning of a new counter period of a counter stage of the clock divider circuit, the clock divider circuit is able to seamlessly transition at the end of one series of clock pulses at a first clock frequency to a second series of clock pulses at a second clock frequency without introducing a pause between the clock pulses of different frequencies and is also able to ensure that no partial clock pulses introduce a glitch at the transition of the clock output signal.

One example application of a clock divider circuit is for power management. As resource requirements of an electronic device increase, the clock frequency supplied to an electronic circuit can be increased. Similarly, as resource requirements of the electronic device decrease, the clock frequency can be decreased. As the clock frequency driving an electronic circuit is increased, the electronic circuit will increase its power consumption. As the clock frequency is decreased, the electronic circuit will decrease its power consumption.

Typically, a clock frequency for an electronic device is selected so that the device will function in its most demanding operational environment. Where the performance demands of the device are not at this peak demand, energy can be wasted if the device continues to operate at this relatively high clock frequency. With a programmable clock divider circuit, however, the clock frequency supplied to the electronic device may be varied depending on the operational demand of the device.

In one implementation, for example, the electronic device, such as a laptop computer, may include many operational settings that may be used depending upon the demand placed on the device. Where full performance is needed, the clock signal may be provided to the electronic circuit at a first, relatively high frequency. Where less performance is needed, however, the clock signal frequency may be reduced to conserve power usage in the electronic device. Where only background processes are running on a laptop computer, for example, the clock signal frequency may be lowered. Where the laptop is placed into a sleep mode, the clock frequency can be lowered further to a very low level that is just enough to maintain the device in the sleep mode.

Similarly, a data storage device, such as a disk drive may operate at different clock frequencies depending upon demand. In one example implementation, for example, where the device is operating in a sequential read or write mode, or has a queue of active commands to be processed, a processor of the device will be operated at 100% of the maximum available clock frequency. Where a series of random reads or writes are being performed, the processor of the device might be operated at 75% of the available clock frequency. Where the device is merely tracking a sector waiting on a read or write command, the processor might be operated at 33% of the available clock frequency. Similarly, where the device is placed into a sleep mode, the processor might be operated at only 1% of the available clock frequency. In this implementation, for example, the clock frequency may be varied based on a number of factors, such as work load and application, environmental needs or concerns, or the like.

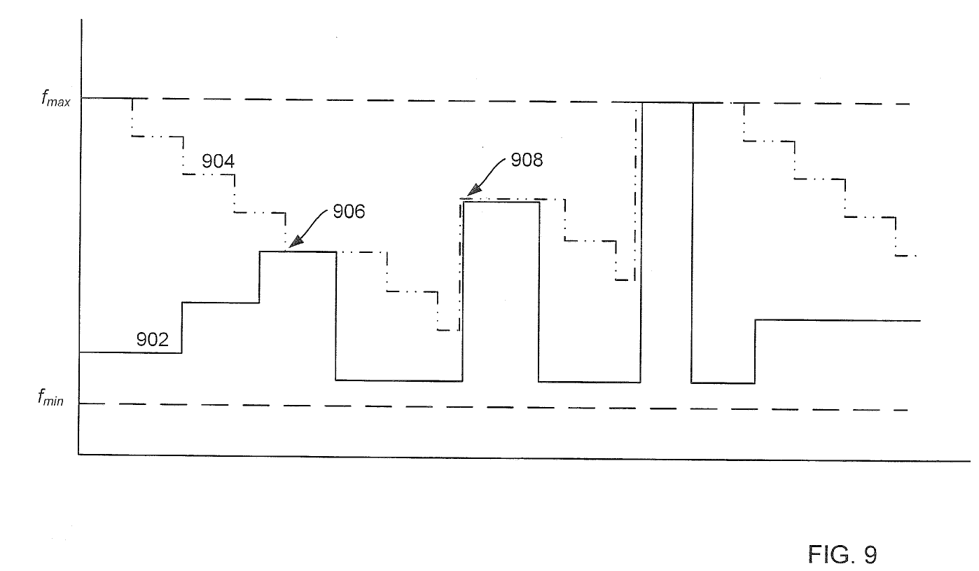

FIG. 9 shows an example timing diagram 900 depicting demand and clock frequency adjustments of an example electronic system. In FIG. 9 the timing diagram 900 shows a maximum operational frequency fₘₐₓ and a minimum operational frequency fₘᵢₙ for an electronic device. Operational demand curve 902 shows the required clock frequency to meet demand being imposed on a processor of the device. Clock frequency curve 904 shows the clock signal frequency being provided to a processor of the device.

In the implementation shown in FIG. 9, the clock frequency 904 starts at fₘₐₓ. As the system determines that the clock frequency being provided is above that required for the current operating conditions, the clock frequency is lowered. In this implementation, for example, the clock frequency curve 904 is lowered in quantized steps until the clock frequency being supplied meets the demand (see, e.g., point 906). The clock frequency can also be lowered in other amounts, such as multiple steps at a time or in one step to a new desired frequency setting.

Where the demand on the device increases (see, e.g., point 908), the clock frequency can be increased at least until the clock frequency is sufficient to meet the demand imposed on the processor of the device. In the implementation of FIG. 9, for example, the clock frequency is raised in one step each time the demand exceeds the clock frequency being supplied. In that manner, performance of the device is not impacted such that the device operates below the demand level as it reacts. Again, however, the clock frequency may be changed in other manners, such as in one or more quantized steps until the clock frequency catches up with the increase in demand.

Certain implementations have been discussed with reference to a disk drive other data storage device. One skilled in the art will recognize that the present invention may also be applied to any electronic device including a processor operating on a clock, such as a magnetic disk drive, an optical disc drive, a magneto-optical disc drive, a compact disc drive, a server, a personal computer, office equipment such as copiers and fax machines, or other electronic devices operating on a clock. The electronic device, for example, may comprise a processor operating instructions comprising software and/or firmware or may comprise logic or circuitry that provides a feedback used for clock selection. Clock selection may also be mode-based. For example, different clock selections may be made for modes comprising different operations of an electronic device, such as a selection of a “picture-in-picture” on a television or recording on one channel while viewing another channel with a set-top box (e.g., a cable or satellite modem) or a personal video recorder.

The technology described herein is implemented as logical operations and/or modules in one or more systems. The logical operations may be implemented as a sequence of processor-implemented steps executing in one or more computer systems and as interconnected machine or circuit modules within one or more computer systems. Likewise, the descriptions of various component modules may be provided in terms of operations executed or effected by the modules. The resulting implementation is a matter of choice, dependent on the performance requirements of the underlying system implementing the described technology. Accordingly, the logical operations making up the embodiments of the technology described herein are referred to variously as operations, steps, objects, or modules. Furthermore, it should be understood that logical operations may be performed in any order, unless explicitly claimed otherwise or a specific order is inherently necessitated by the claim language.

The above specification, examples and data provide a complete description of the structure and use of example embodiments of the invention. Although various embodiments of the invention have been described above with a certain degree of particularity, or with reference to one or more individual embodiments, those skilled in the art could make numerous alterations to the disclosed embodiments without departing from the spirit or scope of this invention. Other embodiments are therefore contemplated. It is intended that all matter contained in the above description and shown in the accompanying drawings shall be interpreted as illustrative only of particular embodiments and not limiting. Changes in detail or structure may be made without departing from the basic elements of the invention as defined in the following claims.

Although the subject matter has been described in language specific to structural features and/or methodological arts, it is to be understood that the subject matter defined in the appended claims is not necessarily limited to the specific features or acts descried above. Rather, the specific features and acts described above are disclosed as example forms of implementing the claimed subject matter.

What is claimed is:

1. A clock divider circuit comprising:
a clock input, a clock selection input, a divider stage and a toggle stage for providing an output clock based on a clock input received at the clock input, the clock selection input coupled to the divider stage and the divider stage coupled to the toggle stage,
wherein a clock divide setting is updated at the clock selection input synchronously to an operation of the divider stage.

2. The clock divider circuit of claim 1 wherein the clock divide setting is updated at the clock selection input synchronously to the operation of the divider stage to provide a seamless transition of the output clock based upon the updated clock divide setting.

3. The clock divider circuit of claim 1 wherein a selection circuit updates the clock divide setting and provides the updated clock divide setting to the clock selection input.

4. The clock divider circuit of claim 3 wherein a synchronizer circuit determines the updated clock divide setting.

5. The clock divider circuit of claim 1 wherein the updated clock divide setting is selected from a plurality of clock settings.

6. The clock divider circuit of claim 1 wherein the updated clock divide setting is selected from a plurality of preprogrammed clock settings.

7. The clock divider circuit of claim 1 wherein the clock divide setting is updated at the clock selection input during a counter period of the divider stage.

8. The clock divider circuit of claim 1 wherein the updated clock divide setting is generated automatically.

9. The clock divider circuit of claim 1 wherein the updated clock divide setting is generated automatically based upon a demand of circuit receiving the output clock.

10. The clock divider circuit of claim 1 wherein the output clock is provided to a processor of an electronic device comprising at least one of the following: a mobile telephone, a digital music player, a personal computer, a laptop computer, a personal data assistant, a video camera, a digital camera, a set-top box, a cable modem, a television, a disk drive, and a data storage device.

11. The clock divider circuit of claim 1 wherein the output clock is provided to an electronic device that uses a clock.

12. A method comprising:
receiving an input clock signal and a first clock divide setting;
providing an output clock signal having a first output clock frequency by dividing the input clock signal based upon the first clock divide setting utilizing a divider stage of a clock divider circuit;
providing an updated second clock divide setting synchronously to an operation of the divider stage; and
transitioning the output clock signal to a second output clock frequency based upon the updated second clock divide setting.

13. The method of claim 12 wherein the operation of transitioning the output clock signal to the second output clock frequency is performed seamlessly.

14. The method of claim 12 wherein a selection circuit updates the clock divide setting and provides the updated clock divide setting to the clock selection input.

15. The method of claim 13 wherein a synchronizer circuit determines an updated clock divide setting.

16. The method of claim 12 wherein the updated clock divide setting is selected from a plurality of clock settings.

17. The method of claim 12 wherein the updated clock divide setting is selected from a plurality of preprogrammed clock settings.

18. The method of claim 12 wherein the updated clock divide setting is provided during a counter period of the divider stage.

19. The method of claim 12 wherein the updated clock divide setting is generated automatically based upon a demand of circuit receiving the output clock.

20. A power management system comprising:
a clock divider circuit comprising a clock input, a clock selection input, a divider stage and a toggle stage for providing an output clock based on a clock input received at the clock input, the clock selection input coupled to the divider stage and the divider stage coupled to the toggle stage,
wherein a clock divide setting is updated in response to a change in demand and provided to the clock divider circuit at the clock selection input synchronously to an operation of the divider stage to provide a seamless transition of the output clock based upon the updated clock divide setting.
